(19) United States
(12) Patent Application Publication
(10) Pub. No.: US 2023/0378276 A1
(43) Pub. Date: Nov. 23, 2023

(54) EPITAXIAL ScxAl1-xN SEMICONDUCTOR DEVICES

(71) Applicant: Comell University, Ithaca, NY (US)

(72) Inventors: Joseph Casamento, Ithaca, NY (US); Ved Gund, Ithaca, NY (US); Debdeep Jena, Ithaca, NY (US); Hyunjea Lee Lee, Ithaca, NY (US); Benyamin Davaji, Ithaca, NY (US); Amit Lal, Ithaca, NY (US); Huili (Grace) Xing, Ithaca, NY (US); Takuya Maeda, Ithaca, NY (US)

(73) Assignee: Cornell University, Ithaca, NY (US)

(21) Appl. No.: 18/198,515

(22) Filed: May 17, 2023

Related U.S. Application Data
(60) Provisional application No. 63/344,270, filed on May 20, 2022.

(51) Int. Cl. H01L 29/20; H01L 29/78; H01L 29/778

(52) U.S. Cl. CPC H01L 29/2003; H01L 29/78391; H01L 29/7786

(57) ABSTRACT

The epitaxial growth of ScₓAl₁₋ₓN—GaN heterostructures and the observation of robust room temperature ferroelectric behavior are disclosed. A semiconductor device, which, for having one or more ScₓAl₁₋ₓN layers of thicknesses in which ferroelectricity can be observed in the one or more ScₓAl₁₋ₓN layers, is a nitride ferroelectric transistor (FeFET), which is also disclosed.

### CROSS-REFERENCE TO RELATED APPLICATIONS

This application claims priority to U.S. Provisional Patent Application No. 63/344,270, entitled EPITAXIAL ScXA11-XN SEMICONDUCTOR DEVICES, filed May 20, 2022, which is incorporated herein by reference in its entirety and for all purposes.

### STATEMENT REGARDING FEDERALLY SPONSORED RESEARCH OR DEVELOPMENT

This invention was made with U.S. Government support from DARPA under the Tunable Ferroelectric Nitrides (TUFEN) program and also from National Science Foundation (NSF) under DMREF grant. 1534303. The U.S. Government has certain rights in the invention.

### BACKGROUND

These teachings relate generally to semiconductor devices including epitaxial Sc₁₋ₓAl₁₋ₓN.

Ferroelectrics are a relatively rare class of materials that possess the ability to reversibly switch their electrical polarization (P) with an applied electric field (E). This phenomenon, coupled with the already existing piezoelectric and pyroelectric behavior present in crystals with lower crystal symmetry, garners tremendous attention in research and technological applications. Specifically, attention has been focused on the downsizing of electronic systems such as piezoelectric actuators, radiofrequency (RF) filters for higher frequency operation, and the development of subthreshold transistors for low voltage applications. The hysteresis in the polarization and electric field relationship in a ferroelectric material allows for memory functionality. Namely, the two stable polarization states in a ferroelectric (e.g., up and down) can be stored as on and off states in an electronic device, respectively. When a ferroelectric layer can be integrated with a semiconductor, a merging of the memory and logic functions is possible.

The existing III-nitride semiconductor materials—GaN, AlN and InN (and their corresponding alloys) boast desirable optoelectronic features such as direct band gaps tunable from the infrared to ultraviolet regime, pyroelectric behavior, and novel heterostructures that form the basis of polarization engineering and polarization-induced doping. Accordingly, the nitrides have found rapidly expanding applications in solid-state lighting, RF and power electronics, and piezoelectric actuators and detectors. For example, GaN based LEDs and Lasers are used extensively in visible and short-wavelength photonics, and GaN based high-electron mobility transistors (HEMTs) form the basis for high frequency RF amplifiers and power electronics. Likewise, AlN is the current material of choice for piezoelectric applications due to high figures of merit stemming from coupled piezoelectric and mechanical behavior.

Until very recently, ferroelectric behavior had not been seen in the III-nitride material family. (See, for example, S. Fichtner, N. Wolff, F. Lofink, L. Kienle, and B. Wagner, J. Appl. Phys. 125, 114103 (2019).). The energy to switch between the stable metal and nitrogen-polar states in the wurtzite crystal was expected to be larger than the energy for dielectric breakdown. Alloying the III-nitrides with transition metals such as scandium (Sc) and yttrium (Y) with predicted large solubility in the wurtzite crystal structure is expected to increase the piezoelectric response and induce ferroelectric response by increasing the ionic bond character and decreasing the energy barrier for polarization, respectively. This has been proven experimentally in sputtered ScxAl1-xN films, with a large piezoelectric enhancement of over 400% for Sc contents up to 40%, and robust ferroelectric behavior for Sc contents as low as 10% and as thin as 20 nm. These developments in conjunction with the relatively low temperatures required for sputter deposition, have led to ScxAl1-xN usage as a complementary metal oxide semiconductor (CMOS) compatible element and its current widespread commercial production. Ferroelectric field-effect transistors can be used to build a type of one-transistor (1T) non-volatile memory.

There is a need for epitaxially deposited ferroelectric materials. Useful devices can be obtained from the epitaxially deposited ferroelectric materials.

### BRIEF SUMMARY

The epitaxial growth of ScₓAl₁₋ₓN—GaN heterostructures and the observation of robust room temperature ferroelectric behavior at a nominal Sc composition of 18% Sc are disclosed. Molecular beam epitaxy (MBE) aims to accomplish this with epitaxial growth on semiconductor bulk single-crystals with low dislocation densities. In addition, the usage of an ultra-high vacuum environment allows for low impurity levels in the resulting ScₓAl₁₋ₓN films. The ferroelectric properties of sputter-deposited films are compared with MBE grown ones that can be integrated with high electron mobility transistors (HEMTs) and light emitting diodes (LEDs). For such devices, low defect densities, low impurity levels, and ultra-thin ScₓAl₁₋ₓN layers are necessary for optimal performance. GaN, finding widespread usage in these optoelectronic applications, as well as being in-plane lattice-matched to ScₓAl₁₋ₓN at ˜18% Sc, is a preferred platform to epitaxially stabilize and study the fundamental properties of wurtzite ScₓAl₁₋ₓN.

In one or more instantiations, the semiconductor device of these teachings includes a not intentionally doped III N layer, III being one or more Group 3 element, an other III N barrier layer, where III includes at least one other III element different from the III element in the not intentionally doped III N layer, the other III N barrier layer being epitaxially deposited on the not intentionally doped III N layer, and a ScₓAl₁₋ₓN layer epitaxially disposed on the other III N barrier. In one instance, the semiconductor device of these teachings also includes a further III N layer, where III includes at least one further III element different from Aluminum, epitaxially deposited on the ScₓAl₁₋ₓN layer. In another instance, the semiconductor device of these teachings includes an n-doped drain region recessed into or disposed on the not intentionally doped GaN layer and in contact with a first end of the other III N barrier layer and with a first end of the ScₓAl₁₋ₓN layer, and, in some instances, in contact with a first end of the further III N layer, and n-doped source region recessed into or disposed on the not intentionally doped GaN layer and in contact with a second end of the other III N barrier layer and with a second end of the ScₓAl₁₋ₓN layer, and, in some instances, in contact with a second end of the further III N layer. In one instance, electrically conductive contacts are disposed on the n-doped source region, on the n doped drain region and an electrically conductive gate contact is disposed between the electrically conductive contacts on the n doped source and drain region and disposed on the ScₓAl₁₋ₓN layer or on the further III N layer. In an illustrative instantiation, the not intentionally doped III N layer is a not intentionally doped Ga N layer, the other III N barrier layer is an AlN layer, and the further III N layer is a GaN layer. In one instance, x is between 0.10 to 0.36. In one instance, ScₓAl₁₋ₓN layer is a ferroelectric layer.

In one or more instances, the ScxAl1-xN layer in the semiconductor device of these teachings is a ferroelectric layer.

For a better understanding of the present teachings, together with other and further objects thereof, reference is made to the accompanying drawings and detailed description and its scope will be pointed out in the appended claims.

### BRIEF DESCRIPTION OF THE DRAWINGS

FIG. 1A shows Symmetric XRD 2theta-omega scans, showing a strong wurtzite 002 ScₓAl₁₋ₓN peak for 100 nm thick ScₓAl₁₋ₓN in the configuration of these teachings shown in the inset;

FIG. 1B shows an AFM image of the configuration of FIG. 1A,

FIG. 1C, shows RHEED image along the [110] zone axis of ScₓAl₁₋ₓN, showing relatively smooth surface morphologies and epitaxial growth on GaN;

FIG. 1D shows the sample used in FIGS. 1A-1C;

FIGS. 2A-2B show P-E loops for 100 nm (2A) and 200 nm (2B) thick ScₓAl₁₋ₓN/n⁺GaN heterostructures, showing hysteresis loops and convergence of remnant polarization and coercive field values at higher applied fields;

FIG. 2C shows representative positive up/negative down (PUND) waveform using trapezoidal voltage pulses on the 200 nm sample, indicating the ability to separate the contributions of polarization switching and electrical leakage to the measured current. Similar behavior is seen for triangular voltage pulses;

FIG. 3 is an overlay of the room temperature P-E loops of sputtered 200 nm Al_{0.78}Sc_{0.22}N with MBE 200 nm and 100 nm Al_{0.82}Sc_{0.18}N; the MBE films have a much lower Pᵣ*_{c}E, product, indicating their suitability in low voltage operation;

FIG. 4A shows the sample structure used in FIGS. 4B-4D;

FIGS. 4B, 4C show the different crystal structures in the ScₓAl₁₋ₓN layer;

FIG. 4D shows the polarization map showing formation of ferroelectric domains;

FIG. 5A shows the structure used in FIGS. 5B-5C;

FIG. 5B shows a plot of current density vs electric field;

FIG. 5C shows a plot of polarization vs electric field;

FIGS. 6A-6B show fabrication of a lateral transistor of these teachings;

FIGS. 7A, 7B show results for the device of FIG. 6B; and

FIG. 8A shows a structure of a lateral transistor of these teaching;

FIG. 8B shows expected results when ScₓAl₁₋ₓN layer, in the structure of FIG. 8A, is ferroelectric;

FIG. 9A shows another structure of these teachings;

FIG. 9B shows Polarization vs. Electric Field for diodes obtained from FIG. 9A;

FIG. 10A depicts a control HEMT used in these teachings;

FIG. 11A shows an instantiation of a HEMT of these teachings;

FIGS. 11A and 11B show, respectively, energy band diagrams for the control HEMT of FIG. 10A and for the HEMT of these teachings shown in FIG. 10B;

FIG. 11C shows measurement for the HEMT of these teachings shown in FIG. 10B;

FIG. 12A shows contact resistances for the control HEMT between the metal and the regrown n+GaN regions and the n+GaN regions and 2DEG;

FIG. 12B shows contact resistances, for the HEMT of these teachings shown in FIG. 10B, between the metal and the regrown n+GaN regions and the n+GaN regions and 2DEG;

FIGS. 12C, 12D shows cross sections of the regrowth region used in the measurement of contact resistances;

FIG. 13A shows representative device process flow of III-Nitride HEMT of these teachings with regrown contacts;

FIG. 13B shows an SEM image of a processed HEMT of these teachings, and inset shows Zoomed-in image of a T-gate;

FIGS. 14A-14D show measured characteristics of the control HEMT with an AlN barrier: !4A shows output characteristics; 14B shows transfer characteristics in the log and (inset) linear scale; 14C shows transconductance vs. Vgs; and 14D shows subthreshold slope vs. drain current;

FIGS. 15A-15D show measured characteristics of the FerroHEMT with an AlScN barrier of these teachings shown in FIG. 10B; 15A shows Output characteristics; 15B shows Transfer characteristics in the log scale showing a counterclockwise hysteresis and sub-Boltzmann slope; 15C shows Transconductance vs. Vgs showing hysteresis, and 15D shows Linear I_{d} vs Vgs showing hysteresis;

FIG. 16A shows the hysteresis loop measured on one FerroHEMT with an AlScN barrier of these teachings shown in FIG. 10B;

FIGS. 16B and 16C show subthreshold characteristics of the FerroHEMT of these teachings used for the measurements of FIG. 16A; behavior observed in the subthreshold slopes with a 20 mV gate sweep steps for 16B and with a 10 mV gate sweep steps for 16C;

FIG. 17A shows the high-frequency characteristics of the AlN barrier control HEMT;

FIG. 17B shows the high-frequency characteristics of one FerroHEMT with an AlScN barrier of these teachings such as shown in FIG. 10B;

FIG. 17C shows speed benchmarks of AlScN HEMT of these teachings with previous designs; and

FIG. 17D shows scaling of output current with gate length of AlScN HEMT of these teachings compared with previous designs.

### DETAILED DESCRIPTION

Although the teachings have been described with respect to various embodiments, it should be realized these teachings are also capable of a wide variety of further and other embodiments within the spirit and scope of the appended claims.

As used in the specification and claims, for the purposes of describing and defining the disclosure, the terms about and substantially are used to represent the inherent degree of uncertainty that may be attributed to any quantitative comparison, value, measurement, or other representation. The terms about and substantially are also used herein to represent the degree by which a quantitative representation may vary from a stated reference without resulting in a change in the basic function of the subject matter at issue. Comprise, include, and/or plural forms of each are open ended and include the listed parts and can include additional parts that are not listed and/or is open-ended and includes one or more of the listed parts and combinations of the listed parts.

For clearer understanding of these teachings, the following definitions are provided.

“Group III” (or “III”), as used here in, refers to a group of elements in the periodic table including what are now called Group 13 elements: boron (B), aluminum (Al), gallium (Ga), indium (In), thallium (Tl).

“III,” as used herein, refers to one of the semiconducting elements and Aluminum or a combination of semiconducting elements and Aluminum or Aluminum from group III. Of the Group III elements, one skilled in the art would know that boron trioxide is not a semiconductor (Boron trioxide is almost always found as the vitreous (amorphous) form; however, it can be crystallized after extensive annealing (that is, under prolonged heat). See www.chemeurope.com/en/encyclopedia/Boron_trioxide.html).) One skilled in the art would also know that thallium trioxide can be a degenerate (very highly doped) semiconductor (see, Richard J. Phillips et al., Electrochemical and photoelectrochemical deposition of thallium(III) oxide thin films, Journal of Materials Research 4, 923-929 (1989) and H. P. Geserich, Phys. Status Solidi 25, 741 (1968)) and is unlikely to be used in a transistor. One skilled in the art would know that Nihonium (the element formerly known as ununtrium) has not been seen as having any oxides since the most stable isotope of Nihonium (Nihonium-286) has a half-life of around 8 seconds and decays into Roentgenium, which is also unstable and part of the copper group (See periodic-table.com/nihonium/).)

To exploit the semiconducting properties of GaN and the ferroelectric properties of the ScₓAl₁₋ₓN materials system, their epitaxial integration is the first step. To this end, molecular beam epitaxy (MBE) aims to accomplish this with epitaxial growth on semiconductor bulk single-crystals with low dislocation densities. In addition, the usage of an ultra-high vacuum environment allows for low impurity levels in the resulting ScₓAl₁₋ₓN films.

The epitaxial growth of ScₓAl₁₋ₓN—GaN heterostructures and the observation of robust room temperature ferroelectric behavior at a nominal Sc composition of 18% Sc are disclosed hereinbelow. In-situ reflection high-energy electron diffraction (RHEED) images for ScₓAl₁₋ₓN indicate epitaxial growth for all layers and suggest that ScₓAl₁₋ₓN maintains a wurtzite crystal structure when grown on top of GaN. X-Ray Diffraction (XRD) shows a strong ScₓAl₁₋ₓN 002 peak, indicative of a wurtzite crystal structure and high crystalline quality. Atomic force microscopy (AFM) images show smooth surface morphologies from epitaxial growth with sub nanometer rms roughness. Pulsed IV measurements at a variety of temperatures and frequencies confirm polarization switching and ferroelectric behavior occurs before electrical conduction (e.g., leakage) starts to dominate at higher applied voltages. The relatively low spontaneous polarization and coercive field values compared to sputter deposited ScₓAl₁₋ₓN control samples indicate several potential technological applications of such epitaxial ferroelectric/semiconductor heterostructures.

It should be noted that the dimensional quantities presented in the figures below are related to the instantiation shown in that figure and that these teachings are not limited only to those dimensional values.

In one or more instantiations, the semiconductor device of these teachings includes a not intentionally doped III N layer, III being one or more Group 3 element, an other III N barrier layer, where III includes at least one other III element different from the III element in the not intentionally doped III N layer, the other III N barrier layer being epitaxially deposited on the not intentionally doped III N layer, and a ScₓAl₁₋ₓN layer epitaxially disposed on the other III N barrier. In one instance, the semiconductor device of these teachings also includes a further III N layer, where III includes at least one further III element different from Aluminum, epitaxially deposited on the ScₓAl₁₋ₓN layer. The composition and thickness of the other III N barrier layer can be selected such that a 2D electron gas forms at a boundary between the other III N barrier layer and the not intentionally doped III N layer. In another instance, the semiconductor device of these teachings includes an n-doped drain region recessed into or disposed on the not intentionally doped GaN layer and in contact with a first end of the other III N barrier layer and with a first end of the ScₓAl₁₋ₓN layer, and, in some instances, in contact with a first end of the further III N layer, and n-doped source region recessed into or disposed on the not intentionally doped GaN layer and in contact with a second end of the other III N barrier layer and with a second end of the ScₓAl₁₋ₓN layer, and, in some instances, in contact with a second end of the further III N layer. In one instance, electrically conductive contacts are disposed on the n-doped source region, on the n doped drain region and an electrically conductive gate contact is disposed between the electrically conductive contacts on the n doped source and drain region and disposed on the ScₓAl₁₋ₓN layer or on the further III N layer. In many instances, the value of “x” is between about 0.1 and about 0.36 and the Scₓ Al₁₋ₓ N layer is a ferroelectric layer.

In one or more other instantiations, the semiconductor device of these teachings includes a not intentionally doped III N layer, III being one or more Group 3 semiconductor elements and a Scₓ Al₁₋ₓ N layer epitaxially disposed on the not intentionally doped III N layer, where a thickness of the Sc x Al1-x N layer is selected such that a 2D electron gas forms at a boundary between the Sc x Al1-x N layer and the not intentionally doped III N layer. (See, for example, O. Ambacher et al., Two dimensional electron gases induced by spontaneous and piezoelectric polarization undoped and doped AlGaN/GaN heterostructures, Journal of Applied Physics, Vol. 87, No. 1, 2000, pp. 334-344, which is incorporated herein by reference in its entirety and for all purposes.) In one instance, the n-doped drain region is recessed into the not intentionally doped III N layer up to or beyond a location of the 2D electron gas forms; and the n-doped source region is recessed into the not intentionally doped III N layer up to or beyond a location of the 2D electron gas forms.

Illustrative instantiations are presented hereinbelow. It should be noted that these teachings are not limited to only the Illustrative instantiations.

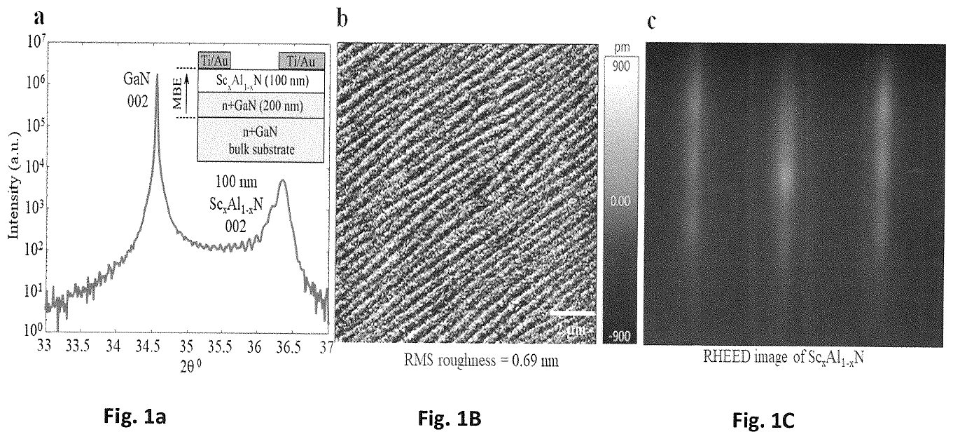

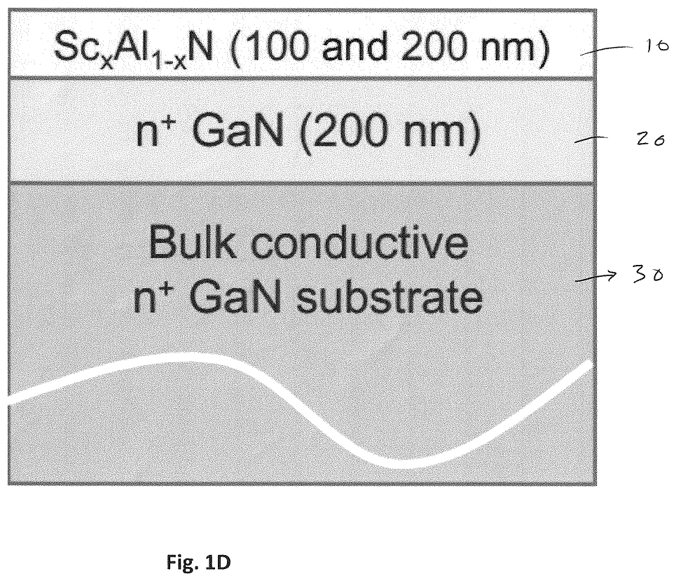

The ScₓAl₁₋ₓN/GaN layer structures studied hereinbelow were grown by plasma-assisted MBE and processed into structures, such as the structure shown in the inset of FIG. 1A (also shown in FIG. 1D). The MBE-grown doped n+GaN layer 20 under the ScₓAl₁₋ₓN layer 10 forms the bottom electrode, and the top electrodes were deposited after the growth. (The substrate 30 is, in this instance, an n-doped GaN substrate.) Details of the epitaxial process and measurement and characterization techniques are described in the methods section of Ferroelectricity in Polar ScAlN/GaN Epitaxial Semiconductor Heterostructures, arXiv:2105.10114 [cond-mat.mtrl-sci], which is enclosed in U.S. Provisional Patent Application No. 63/344,270.

The XRD scan of the heterostructure in FIG. 1A shows a strong wurtzite ScxAl1-xN peak with thickness fringes indicative of a smooth interface. The AFM image shown in FIG. 1B indicates a smooth surface morphology with a rms roughness of 0.69 nm on a 10×10 μm scale that result from the epitaxial growth on a single-crystal substrate. The in-situ RHEED image shown in FIG. 1C indicates epitaxial growth on GaN of single-crystalline ScxAl1-xN, with primary streak azimuths preserved along the [110] zone axis. Combined, these data suggest wurtzite ScxAl1-xN with no signs of secondary phases and crystal misorientations. Spots observed along the primary streaks in RHEED indicate a relatively three-dimensional growth mode, which is expected for nitrogen-rich growth conditions needed for the growth of smooth, and highly crystalline ScxAl1-xN.

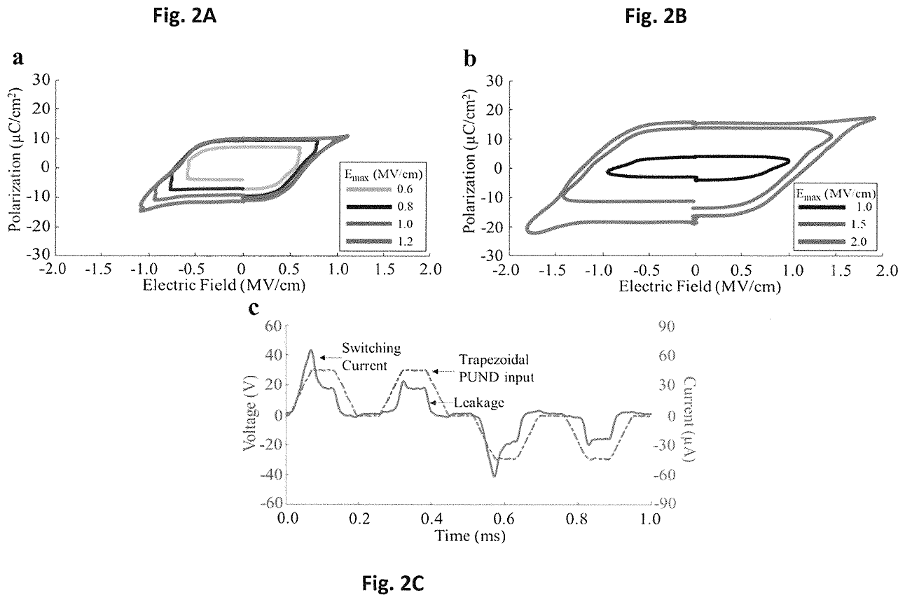

FIGS. 2A and 2B show the measured polarization-electric field (P-E) loops for the ScxAl1-xN/GaN structures where the thickness of the ScxAl1-xN layers are 100 nm (FIG. 2A) and 200 nm (FIG. 2B). As shown in FIG. 2C for the 200 nm ScxAl1-xN/GaN structure, the polarization switching current is observed in the P and N pulses and is calculated by subtracting the currents in the U or D pulses, respectively. The U and D pulses are referred to as the “non-switching” pulses and they do not contain any switching current for a stable ferroelectric material. For a ferroelectric that is completely switched (e.g., very few or no misoriented domains exist), the calculated remnant polarization should remain constant as the electric field value is increased. The trend seen in FIGS. 2A, 2B is observed for all the ScxAl1-xN samples that show ferroelectricity. At low electric fields, the hysteresis loops do not “close,” indicative of incomplete switching. The calculated remnant polarization values and measured coercive field also do not converge to a consistent value for the same reason. At higher electric fields, the remnant polarization and coercive field converge to consistent values of ˜10 μC/cm2 and 0.7 MV/cm and ˜15.5 μC/cm2 and 1.2 MV/cm for the 100 nm and 200 nm thick ScₓAl₁₋ₓN films, respectively. This is indicative of ferroelectric switching. Overall, these values and trends are consistent among several electrodes in each sample as discussed later, confirming repeatable ferroelectric behavior.

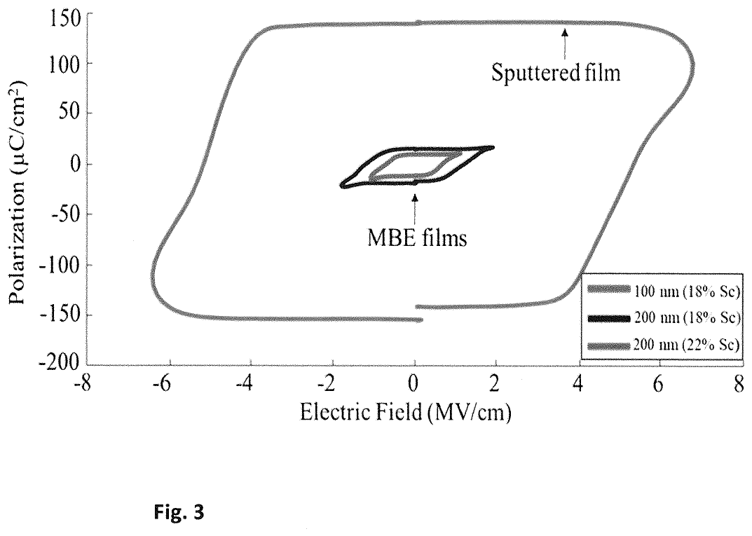

The measured remnant polarization and coercive field values are significantly lower than those measured in sputter-deposited ScₓAl₁₋ₓN films. As pointed out above, the ScₓAl₁₋ₓN films grown by MBE show significantly reduced coercive fields and remnant polarization values compared to the sputter-deposited films, as indicated in FIG. 3. Table 1 summarizes the values as a comparative study between various ScₓAl₁₋ₓN films measured with the same ST setup.

TABLE 1
Comparison of sputter deposited and MBE-grown ScₓAl₁₋ₓN, with
deposition method/thickness, electrode materials, Sc atomic percentage,
coercive field (E_{c}) and remnant polarization (Pᵣ) values given

| Deposition | | | | |
|---|---|---|---|---|
| method and | Bottom Electrode/ | | E_{c} | Pᵣ |
| thickness | Top Electrode | Sc % | (MV/cm) | (μC/cm²) |
| Sputter (200 nm) | 200 nm Pt/200 nm Mo | 22 | 5.3 | 139 |
| MBE (200 nm) | GaN/200 nm Au | 18 | 1.2 | 15.2 |
| MBE (100 nm) | GaN/200 nm Au | 18 | 0.65 | 10.0 |

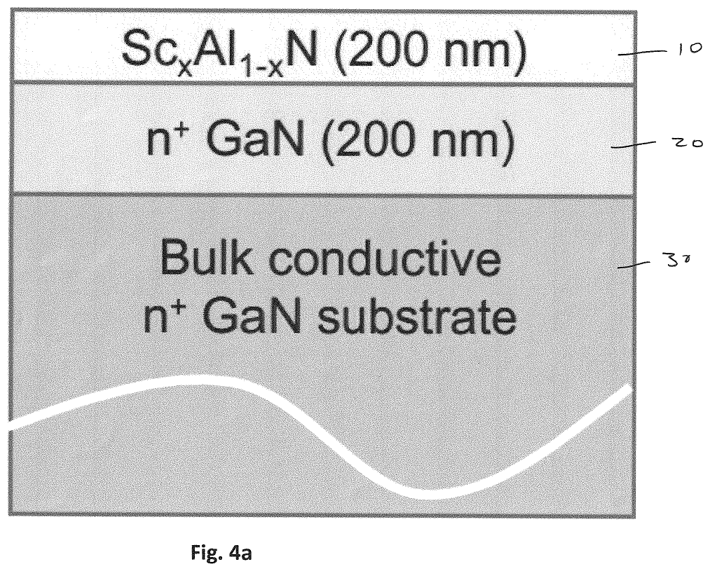

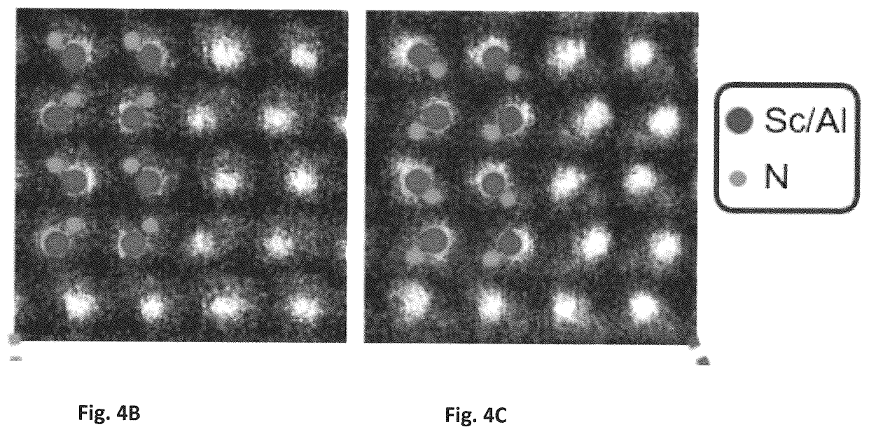

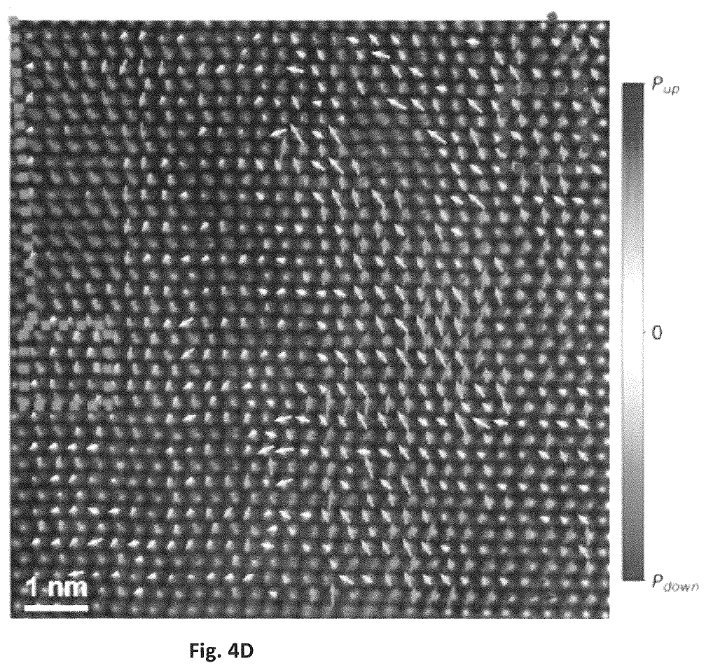

FIG. 4A shows the sample structure used in FIGS. 4B-4D (similar to the structure shown in FIG. 1B). FIGS. 4B, 4C show the different crystal structures in the ferroelectric domains of the ScₓAl₁₋ₓN layer. FIG. 4B shows a Nitrogen polar region. FIG. 4C shows a metal polar region. FIG. 4D shows the polarization map showing formation of ferroelectric domains. In FIG. 4D, polarization points up(red) and down (blue) along c axis, showing formation of ferroelectric domains.

As shown in FIGS. 4B-4C, ferroelectric domains are metal and nitrogen polar, respectively.

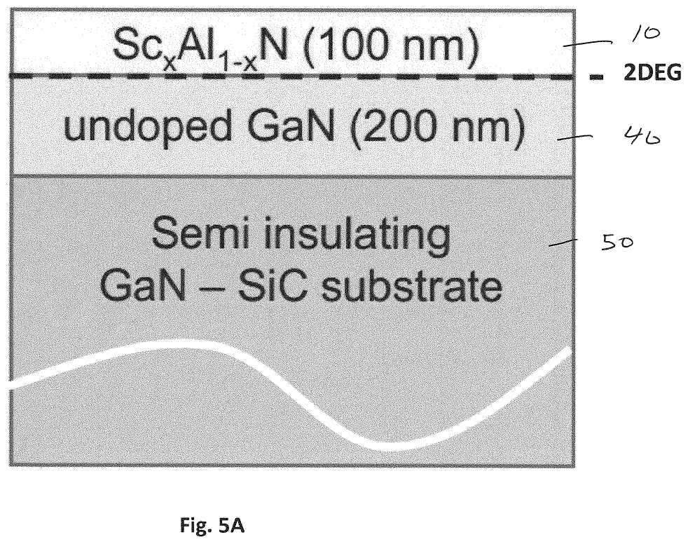

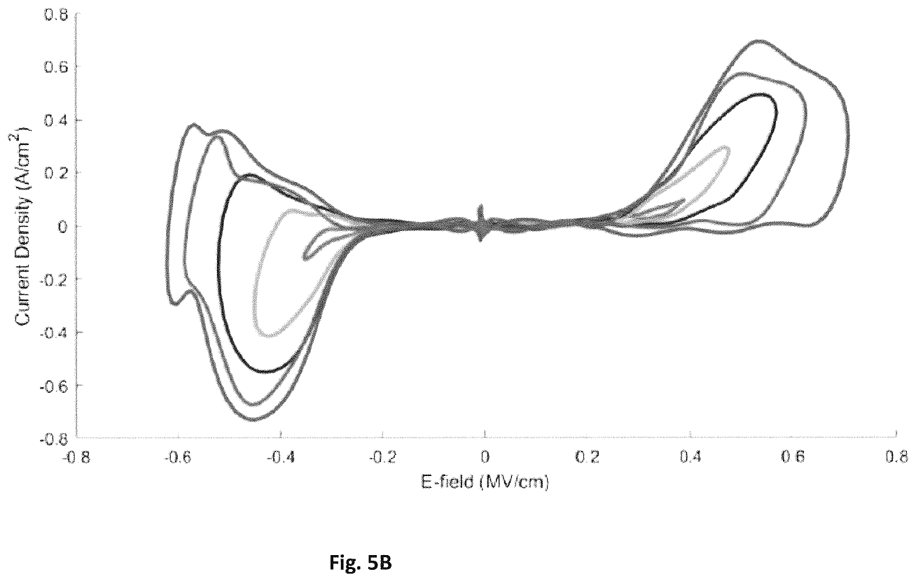

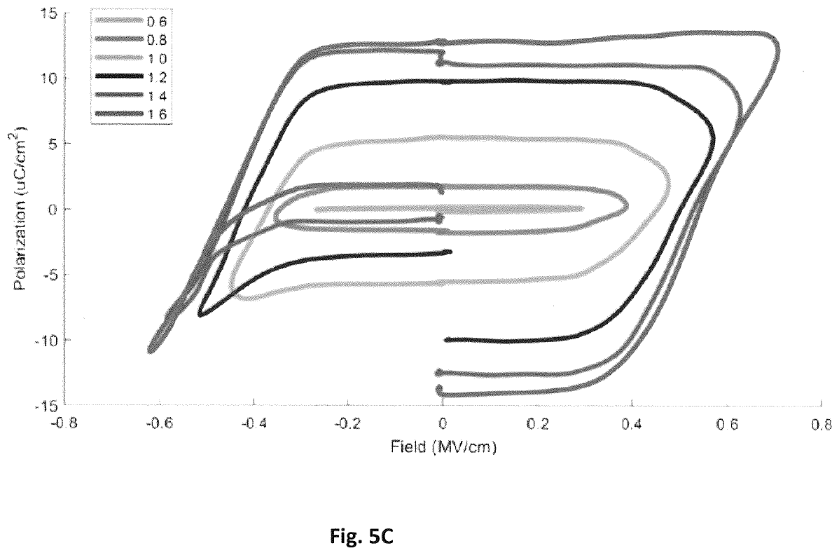

FIG. 5A shows the sample structure used in FIGS. 5B-5C. Referring to FIG. 5A, in the instantiation shown therein, a not intentionally doped GaN layer 40 is deposited on a semi-insulating substrate 50 (GaN—SiC in one instance) and the ScₓAl₁₋ₓN layer 10 is deposited on the not intentionally doped GaN layer 40. A 2DEG is formed at the boundary between the ScₓAl₁₋ₓN layer 10 and the not intentionally doped GaN layer 40. FIG. 5B shows a plot of current density vs electric field for the sample structure shown in FIG. 5A. FIG. 5C shows a plot of polarization vs electric field for the sample structure shown in FIG. 5A. Referring to FIG. 5A, the 2DEG, formed during growth, is the electron channel for the device. Referring to FIGS. 5B, 5C, polarization-electric field hysteresis indicates that the electron-channel, or two-dimensional electron gas (2DEG), is present. FIGS. 5B and 5C are indicative of ferroelectricity in ScₓAl₁₋ₓN and 2DEG at ScₓAl₁₋ₓN—GaN interface.

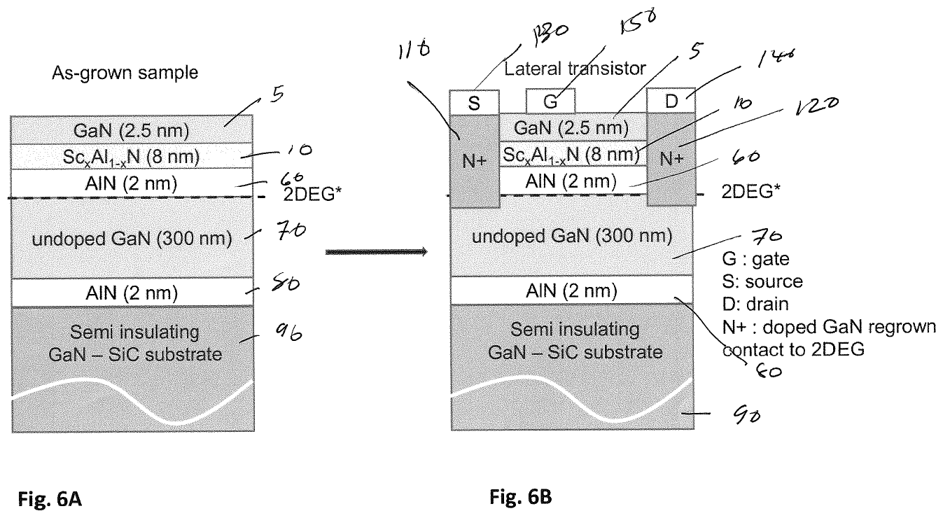

FIGS. 6A-6B show fabrication of an instantiation of a lateral transistor of these teachings. Referring to FIG. 6A, in the instantiation shown therein, an AlN barrier layer 80 is grown on a semi-insulating substrate 90 (GaN—SiC in one instance), a not intentionally doped GaN layer 70 is deposited the AlN barrier layer 80, an AlN layer 60 is deposited on the not intentionally doped GaN layer 70, the ScₓAl₁₋ₓN layer 10 is deposited on the AlN layer 60, and a cap GaN layer 5 is deposited on the ScₓAl₁₋ₓN layer 10. A 2DEG is formed at the boundary between the not intentionally doped GaN layer 70 and the AlN layer 60. In FIG. 6B, an n-doped source region 110 is regrown from being recessed into or disposed on the not intentionally doped GaN layer 70 to at least a top surface of the cap GaN layer 5 and an n-doped drain region 120 is regrown from being recessed into or disposed on the not intentionally doped GaN layer 70 to at least a top surface of the cap GaN layer 5. A first electrically conducting contact 130 is disposed on the n-doped source region 110, a second electrically conducting contact 140 is disposed on the n-doped drain region 120, and an electrically conductive gate contact 150 is disposed between the electrically conductive contacts 130, 140 on the n doped source region 110 and the n doped drain region 120 and disposed on the GaN cap layer 5. In FIGS. 6A-6B, G refers to gate, S denotes a source region, D denotes a drain region, and N+denotes an n-doped GaN regrown contact to the 2DEG, where the terms and gate, source, drain are used in the manner that they are used in reference to a Field effect transistor. The lateral transistors, with the 2DEG as the electron channel, are fabricated in a facility suitable for fabricating microelectronics and nanostructures.

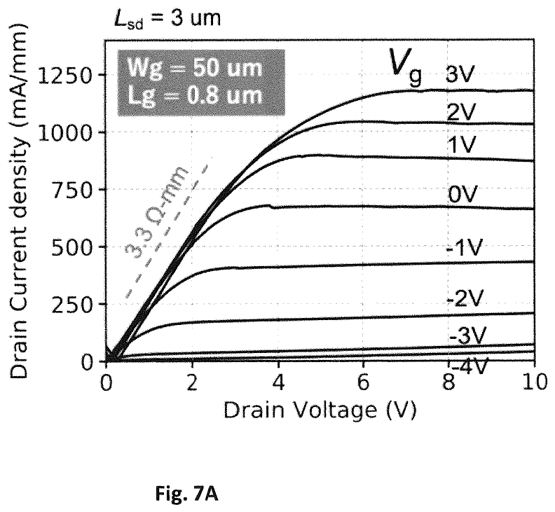

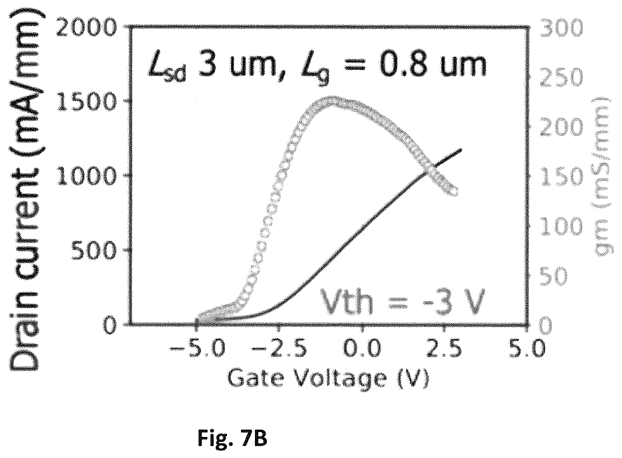

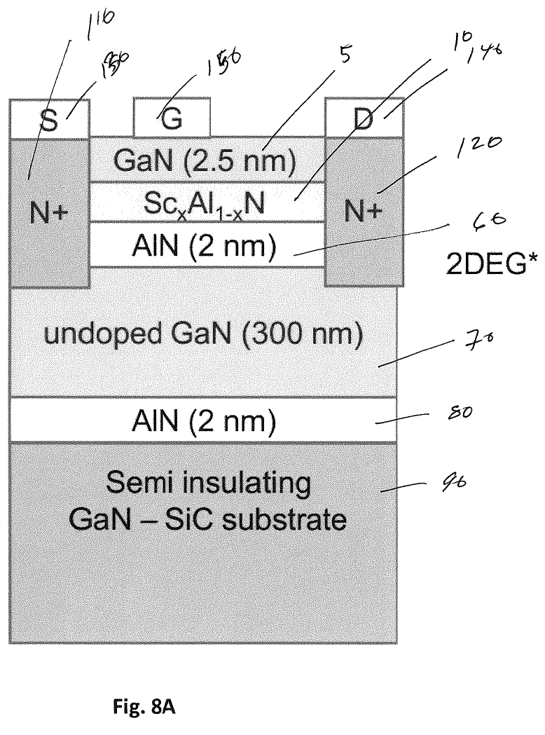

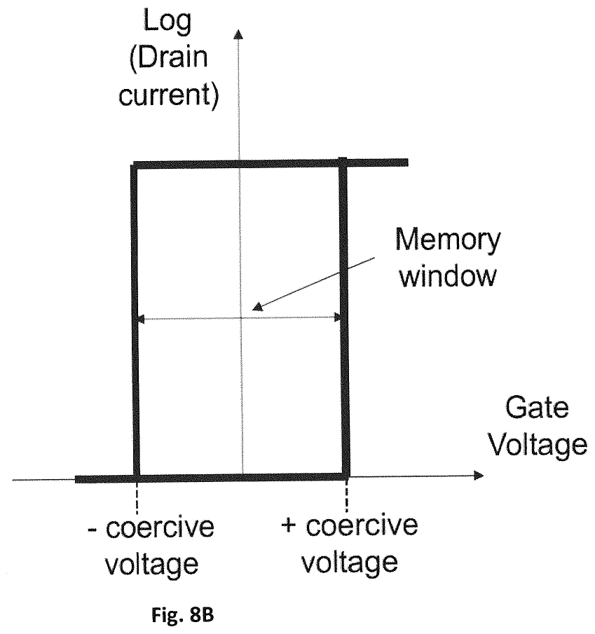

FIGS. 7A, 7B show results for the device shown in FIG. 6B. FIG. 7A shows drain current modulation, at a number of gate voltages, with saturation at high drain voltage. FIG. 7B shows the drain current and the transconductance (gₘ) as a function of the gate voltage. Electron channel pinch-off at negative bias (˜−5 V). Normal lateral transistors were fabricated, with clear modulation and saturation of current in electron channel. However, ferroelectric behavior may depend on layer thicknesses. Although instances were observed where ferroelectric behavior was not observed at a layer thickness of 8 nm, applicants, at the instance of this writing, are not aware that such behavior is due to a limitation. While for other ferroelectric materials, it has been observed that there is a threshold thickness (such as 5 nm) below which ferroelectric behavior is not observed (see, for example, Polking, M., Han, MG., Yourdkhani, A. et al. Ferroelectric order in individual nanometre-scale crystals. Nature Mater 11, 700-709 (2012)), at the time of these writings, what the threshold thickness is for ferroelectric behavior in ScₓAl₁₋ₓN has not been ascertained. Therefore, for ferroelectric behavior, a layer of ScₓAl₁₋ₓN should have a thickness between 2 nm to 1000 nm, preferably between 10 nm to 1000 nm. (A thickness of the ScₓAl₁₋ₓN layer 10 is not identified in FIG. 8A.)

Thicknesses of other materials are selected according to the function being performed by that layer of material. For example, GaN layers from 2 nm to over 300 nm are shown in the instantiations and there is no reason to limit the thickness other than it should be selected to be adequate with the purpose for which it was intended. AlN layers are used as inter-layers in the instantiation shown and, when used for that purpose, the AlN layers should be thin, of the order of 1 nm to 3 nm.

FIG. 8A shows a structure of a lateral transistor of these teaching (similar to that shown in FIG. 6B). The indicators G, D, N+have the same meaning as in FIG. 6B. For thicknesses in which ferroelectricity can be observed in ScₓAl₁₋ₓN layers, a nitride ferroelectric transistor (FeFET) is obtainable. FIG. 8B shows expected results when ScₓAl₁₋ₓN layer, in the structure of FIG. 8A, is ferroelectric.

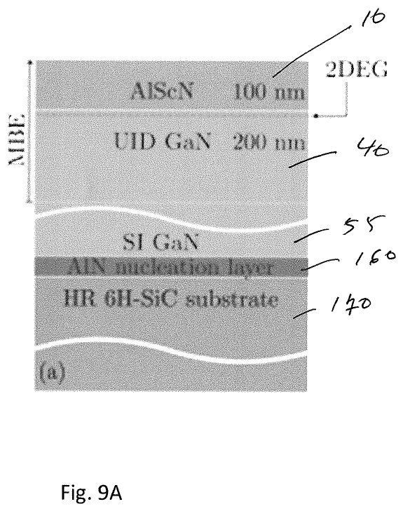

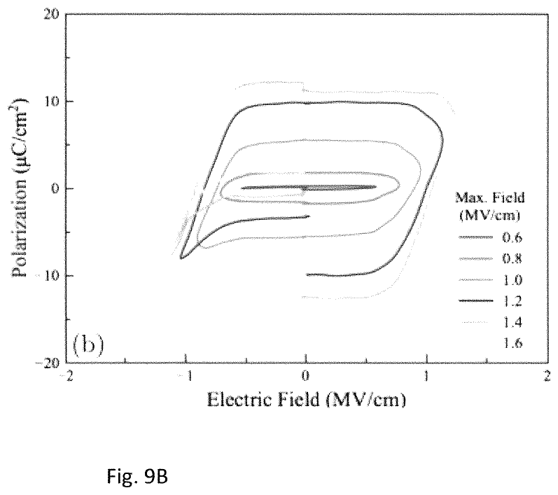

Another illustrative instantiation, similar to FIG. 5A, is shown in FIG. 9A. FIG. 9A shows a test layer structure comprising of a 200 nm not intentionally doped (UID) GaN layer 40 grown by MBE followed by a 100 nm AlScN layer 10 with 18% Sc. The not intentionally doped (UID) GaN layer 40 is grown on a SI GaN layer 55, which is disposed on an AlN barrier layer 160, which is disposed on a substrate 170. A 2DEG is formed at the boundary between the not intentionally doped GaN layer 40 and the AlScN layer 10. A polarization-induced 2D electron gas (2DEG) of density 1.8×10¹³/cm2 and mobility of 377 cm2/V·s was observed in this heterostructure by Hall-effect measurement at room temperature. Using a deposited top electrode and the 2DEG as a bottom electrode, and applying positive-up-negative-down (PUND) voltage pulses and tracking the currents, the polarization-electric field (P-E) loops extracted are shown in FIG. 9B which indicate the epitaxial AlScN layer on UID GaN is ferroelectric with a coercive field E_{c} ˜0.9 MV/cm.

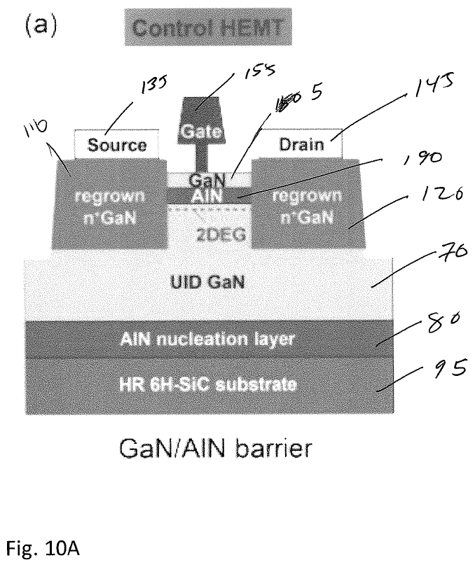

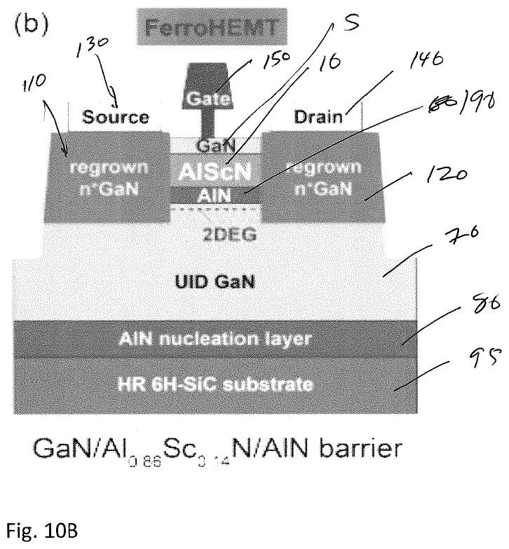

In yet another illustrative instantiation, a control AlN/GaN HEMT and a 14% targeted Sc composition AlScN/AlN/GaN FerroHEMT structure (shown in FIGS. 10A, 10B) were grown by MBE directly on semi-insulating 6H-SiC substrates 95 with a 300 nm AlN nucleation layer 80 and a 1 μm GaN buffer layer (not shown) using methods referred to above to study ferroelectric gating behavior. Referring to FIGS. 10A, 10B, a not intentionally doped GaN region 70 is grown on the AlN nucleation layer 80 and a 1 μm GaN buffer layer (not shown), an AlN layer 190 is grown on the not intentionally doped GaN region 70. A 2DEG is formed at the boundary between the not intentionally doped GaN layer 40 and the AlN layer 190. In FIG. 10A, a GaN cap layer 5 is grown on the AlN layer 190. In FIG. 10B, an AlScN layer 10 is grown on the AlN layer 190 and a cap GaN layer 5 is deposited on the AlScN layer 10. In FIGS. 10A, 10B, an n-doped source region 110 is regrown from being recessed into or disposed on the not intentionally doped GaN layer 70 to at least a top surface of the cap GaN layer 5 and an n-doped drain region 120 is regrown from being recessed into or disposed on the not intentionally doped GaN layer 70 to at least a top surface of the cap GaN layer 5. A first electrically conducting contact 135 is disposed on the n-doped source region 110, a second electrically conducting contact 145 is disposed on the n-doped drain region 120, and an electrically conductive gate contact 155 is disposed between the electrically conductive contacts 135, 145 on the n doped source region 110 and the n doped drain region 120 and disposed on the GaN cap layer 5.

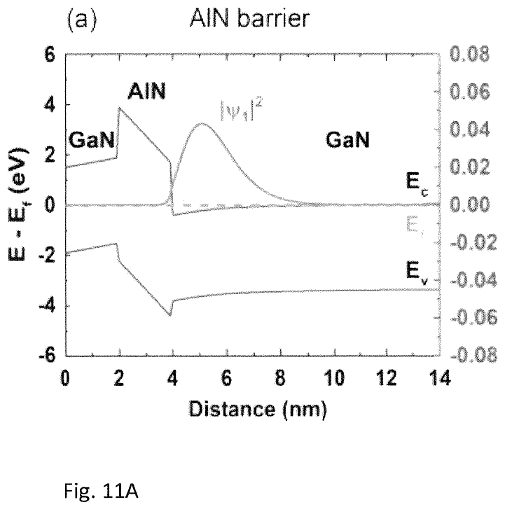

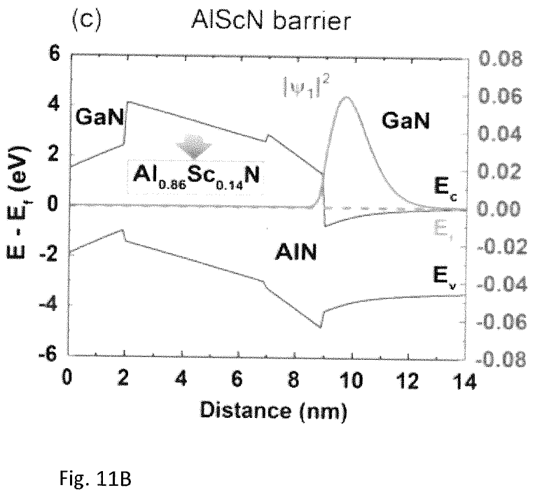

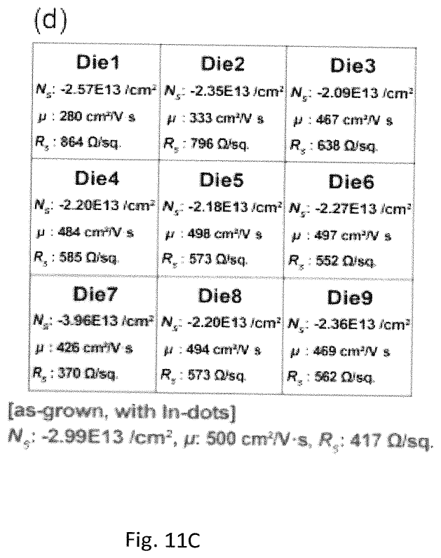

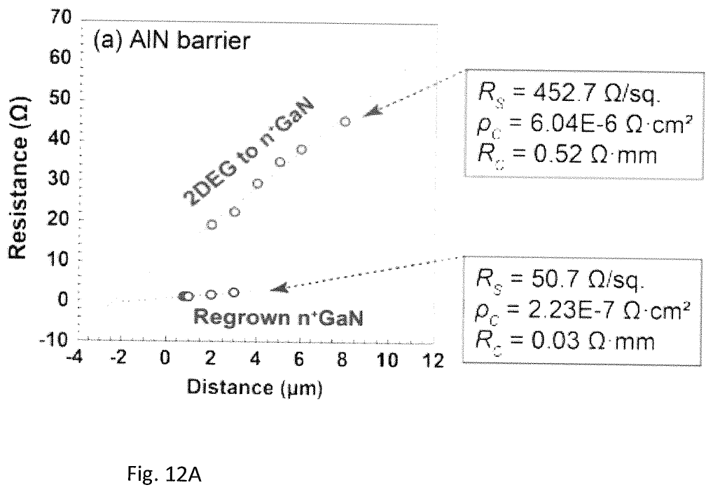

FIGS. 11A and 11B show the corresponding energy band diagrams from the top surface, calculated using self-consistent Schrodinger-Poisson solutions. 2DEG channels are expected at the heterojunctions as shown as ψ²₁ at respective depths. To form Ohmic contacts to these 2DEGs, lithographically defined etching and regrowth of heavily doped n+GaN (N_{d}˜10²⁰/cm³ Si) was performed by MBE. Measured 2DEG densities (obtained from the measurements for 9 Dies shown in FIG. 11C) are consistent with the expected values from the calculation.

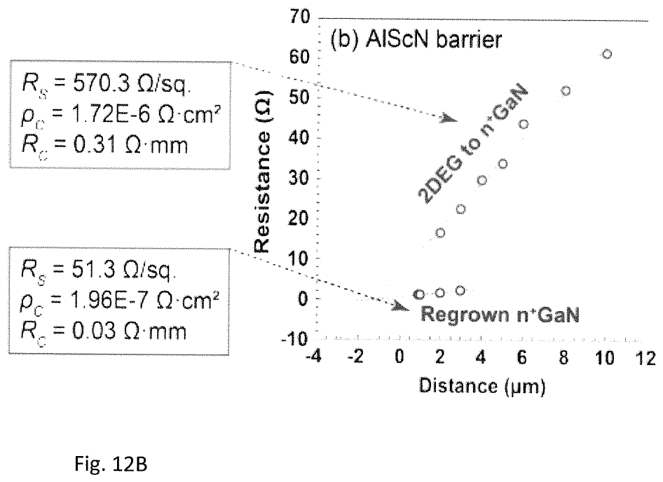

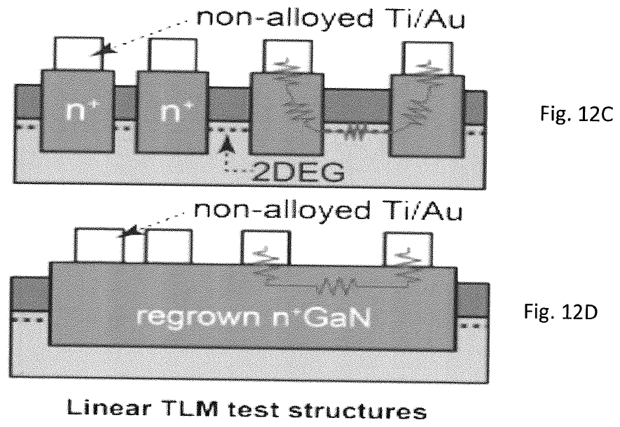

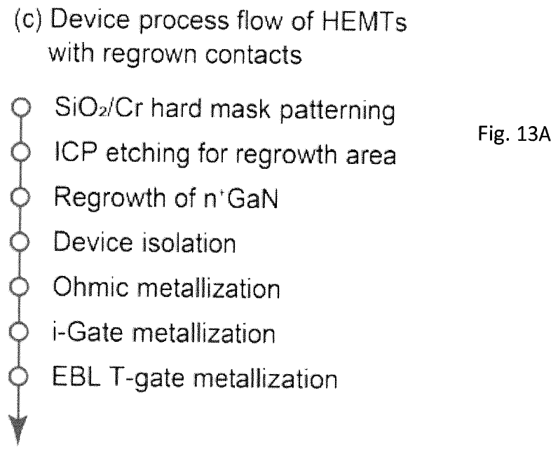

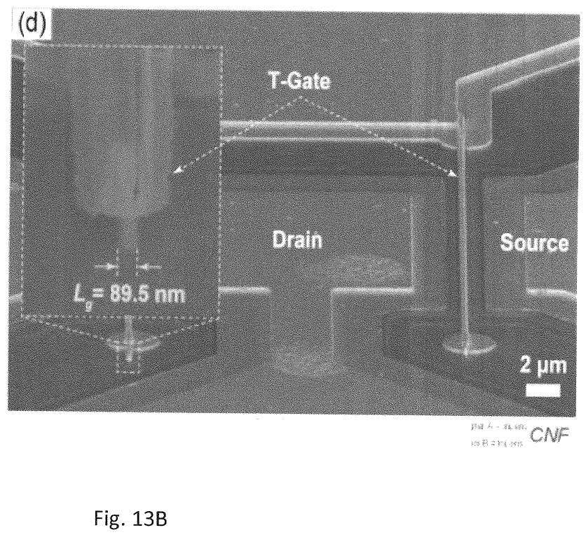

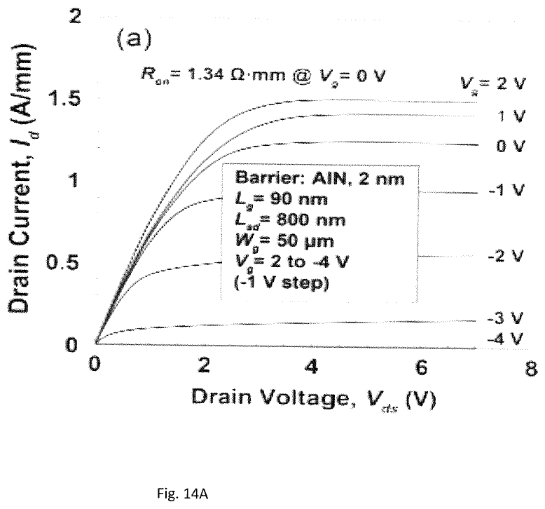

FIGS. 12A and 12B show the resistances of metal-regrown n+GaN (low) and n+GaN-2DEG (moderate, not exceptionally low). (FIGS. 12C, 12D show a cross sections of the regrowth region used in the measurement.) FIGS. 10A, 10B show the control AlN barrier HEMT and the AlScN barrier FerroHEMT cross sections respectively. FIG. 13A shows the representative device process flow of HEMTs with regrown contacts. A SiO₂/Cr hard mask defined the source/drain regions. Ti/Au source/drain was deposited on the n+GaN, and Ni/Au gate was deposited. Electron beam lithography (EBL) process was performed to fabricate T-gate devices for RF and mm-wave performance. FIG. 13B and the inset show SEM images of the final transistor structures. Gate lengths, for this illustrative instantiation, range from about 90 nm to about 18 μm.

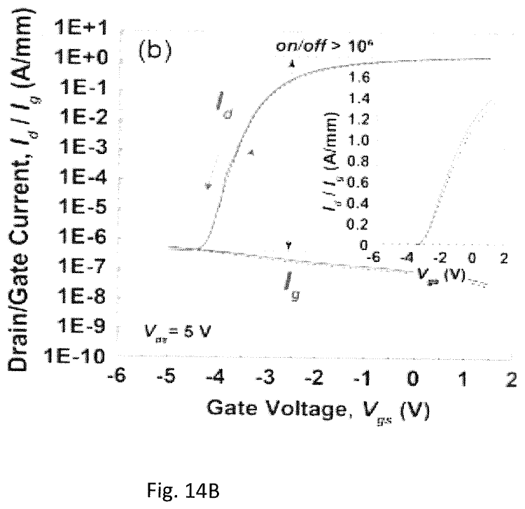

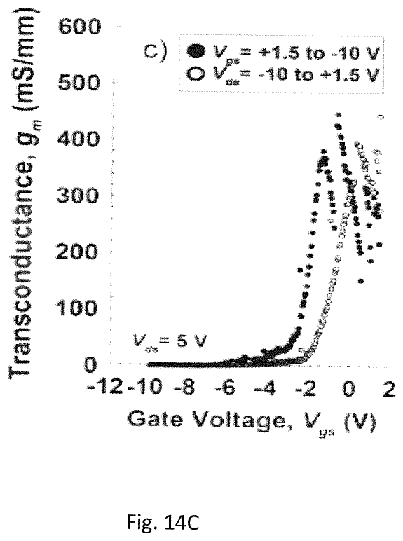

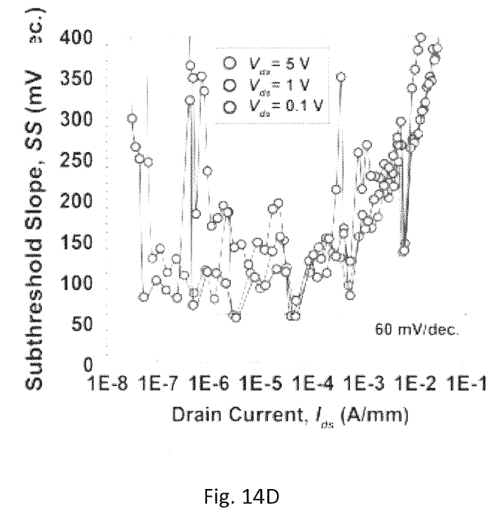

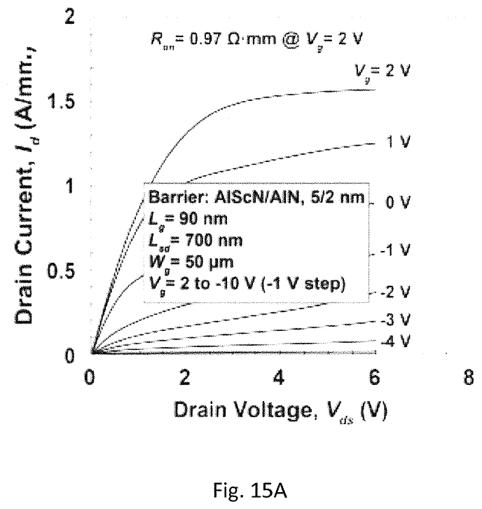

FIGS. 14A and 14B show the measured I_{d}−V_{ds} output characteristics and I_{d}−V_{gs} transfer characteristics of the control AlN/GaN HEMT sample respectively. An on current of ˜1.5 A/mm with an on resistance of Rₒₙn=1.34 Ω·mm, an on/off ratio of 10⁶ limited by gate leakage, with a threshold voltage of ˜−3.5 V were observed. FIG. 14C shows a peak transconductance of ˜0.5 S/mm with a barrier thickness of 2 nm GaN+2 nm AlN. The subthreshold slope shown in FIG. 14D indicates very good normal transistor behavior, grazing the ideal Boltzmann limit of ˜60 mV/decade. The control HEMT thus exhibits excellent performance, as borne out by its RF performance discussed subsequently.

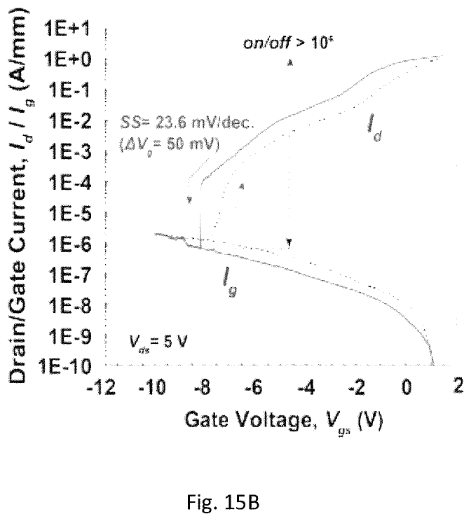

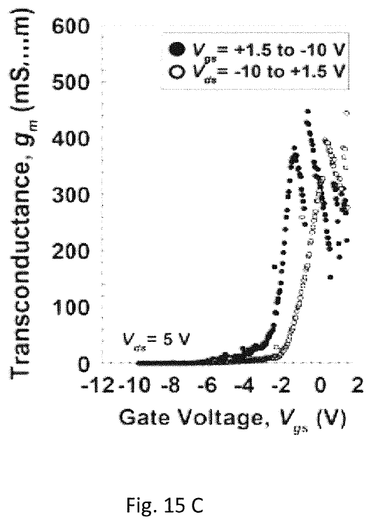

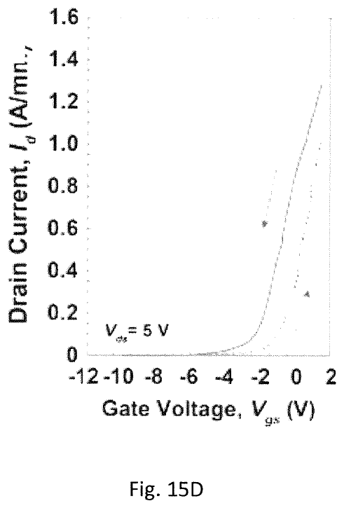

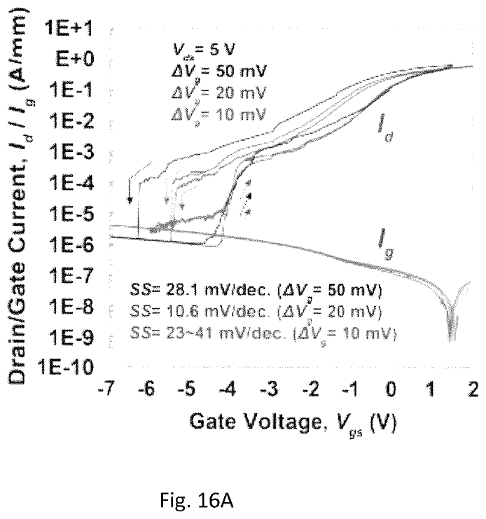

FIGS. 15A-15D show the transistor characteristics when a 5 nm thick epitaxial AlScN barrier layer is added between the AlN and the GaN cap layer, as indicated in FIGS. 10A-10B. From FIG. 15A, the maximum I_{d} still reaches ˜1.5 A/mm at the same gate voltage, in spite of a more than double barrier thickness of 2 nm GaN+5 nm AlScN+2 nm AlN compared to the control sample. This is a result of the high-K dielectric property of AlScN as was reported in J. Casamento et al., Epitaxial ScxAl1-xN on GaN exhibits attractive high-K dielectric properties, Applied Physics Letters, vol. 120, p. 152901, 2022, also provided in U.S. Provisional Patent Application No. 63/344,270, entitled EPITAXIAL ScXAl1-XN SEMICONDUCTOR DEVICES, filed May 20, 2022, both of which are incorporated herein by reference in their entirety and for all purposes. The I_{d}-V_{ds} curves indicate a higher output conductance, but a far larger difference from the control sample is observed in the transfer characteristics in FIG. 15B. A counterclockwise (CCW) hysteresis loop develops in the subthreshold characteristics. A sub-Boltzmann steep slope of 23.6 mV/decade is observed for the on→off voltage sweep. Such repeatable loops are observed in multiple devices. This translates to a hysteretic transconductance curve as seen in FIG. 15C and drain current as seen in FIG. 15D. Note that though the peak transconductance is lower than the control HEMT, the hi-K AlScN helps maintain a high value in spite of a more than double barrier thickness.

The hysteresis window of the threshold voltage is between 1.0-2.0 V as seen in FIGS. 15C and 15D. These observations are strong signatures of both high-K dielectric, and ferroelectric gating behavior. Based on the AlScN barrier thickness (t_{AlScN}), a voltage drop E_{c}×t_{AlScN}˜0.5 V across the AlScN layer is consistent with a low Ec˜1.0 MV/cm. A large portion of the gate voltage still drops across the GaN and AlN layers between the gate metal and the 2DEG channel.

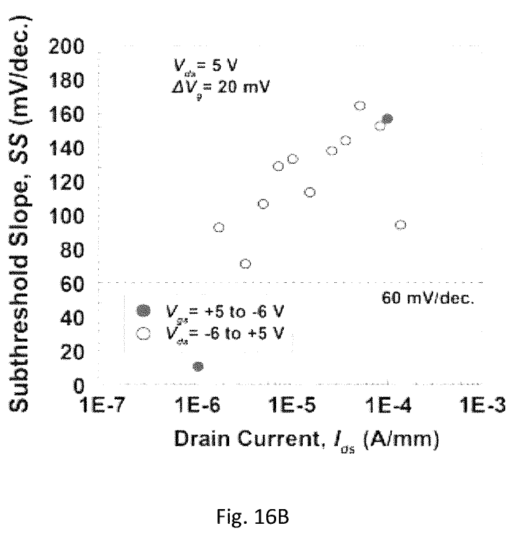

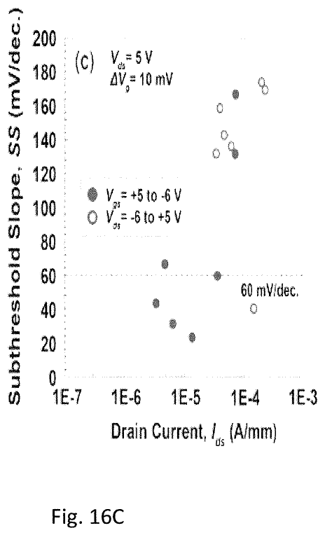

FIG. 16A shows the hysteresis loop measured on Die 7 of FIG. 11C. Several CCW hysteresis loops based on the voltage step of the measurement are shown in FIG. 16A, and the corresponding subthreshold slopes are plotted in FIGS. 16B and 16C. While the majority of the sub-Boltzmann steep slopes are observed in the left-going voltage sweeps, some also appear in the right-going sweeps. It is well known that trapping behavior could lead to false conclusions of ferroelectricity. The CCW loops for n-channels provide strong evidence of ferroelectric FETs. Moreover, the absence of such behavior in the control HEMT sample, and the symmetry, voltage width, and sub-Boltzmann slopes of the FerroHEMT conclusively indicates ferroelectric gating in the all-epitaxial AlScN/GaN devices.

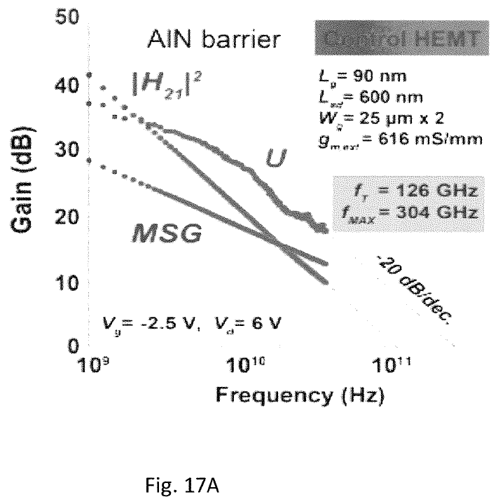

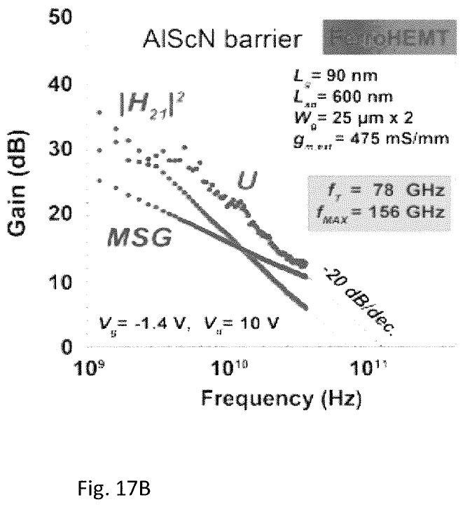

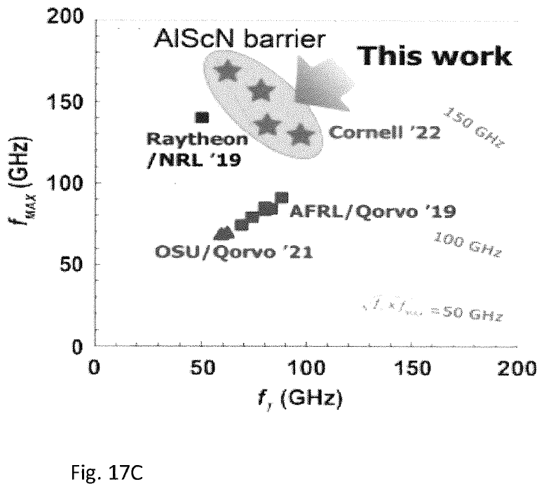

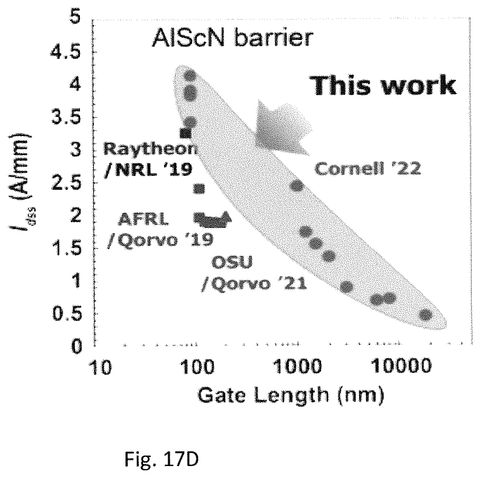

FIG. 17A shows the high-frequency characteristics of the AlN barrier control HEMT. It exhibits excellent cutoff frequencies of f_{T}/f_{MAX}=126/304 GHz for a gate length of L_{g}=90 nm. The device dimensions and bias conditions are indicated in the plot. FIG. 17B shows the measured values for a FerroHEMT of these teachings of similar dimensions but different bias conditions due to the shifted threshold characteristics. It exhibits lower cutoff frequencies of f_{T}/f_{MAX}=78/156 GHz. Even though the values of the AlScN FerroHEMT are lower than the control AlN barrier HEMT, they are the highest reported to date for AlScN barrier transistors, as indicated in FIG. 17C. Furthermore, the FerroHEMTs of these teachings are the fastest ferroelectric transistors reported to date: a maximum FerroHEMT f_{MAX}=168 GHz is measured. The higher speed of the control sample is due to the (expected) higher maximum g_{m,ext}=0.616 S/mm of the control HEMT compared to g_{m,ext}=0.475 S/mm for the FerroHEMT, indicating higher speed FerroHEMTs are possible with further scaling and within the scope of these teachings. FIG. 17D shows the scaling of the output current I_{d}^{max} in the AlScN FerroHEMTs when L_{g} is scaled from 18 μm to 90 nm. An exceptionally high value of 2.5 A/mm is observed for an optical gate length of 1 μm. The deep submicron electron beam lithography (EBL) gates reach record values of 4 A/mm at 90 nm gate length. These record high on-currents are enabled by the high 2DEG density generated by the large difference in polarization between GaN and the epitaxial AlScN layers.

The moderate FerroHEMT channel mobility in FIG. 11C can be improved by 3× for better RF and mm-wave performance in FerroHEMTs of these teachings. The high-K value of AlScN will increase the breakdown voltage in FerroHEMTs by reducing the gate leakage. A negative Drain-induced barrier lowering (DIBL) effect is predicted (see, for example, Y.-H. Liao et al., IEEE Electron Device Lett., vol. 40, p. 1860, 2019), but this will be achievable with careful geometrical design of epitaxial FerroHEMTs of these teachings. Thus, FerroHEMTs of these teachings with thinnest epitaxial ferroelectric barriers show steep subthreshold slopes and deliver the highest on-currents (4 A/mm), and highest speed (f_{MAX}>150 GHz) in all ferroelectric transistors.

The ScₓAl₁₋ₓN/GaN heterostructures of these teachings were grown by MBE in a Veeco® GenXplor system with a base pressure of ˜10-10 Torr on conductive n-type bulk GaN substrates for electrical measurements. Purified elemental Sc (from Ames Laboratory) of nominally 99.9% purity (including C and O impurities), Aluminum (99.9999% purity), gallium (99.99999% purity), and silicon (99.9999% purity) were supplied using Knudsen effusion cells. Nitrogen (99.99995%) active species were supplied using a Veeco® RF UNI-Bulb plasma source, with total chamber pressure of approximately 10-5 Torr during growth. In one instantiation, the RF plasma power was kept at 200 W, and the total gas flow rate was 1.95 sccm. The growth temperature mentioned is the substrate heater temperature measured by a thermocouple. The homoepitaxial GaN layers were grown under standard metal-rich conditions at a temperature of ˜595° C. This layer was doped heavily with the shallow donor dopant Silicon at a density of ˜2×1019/cm3 to form the bottom electrode. Sc and Al atomic percentages in the film were adjusted by the ratio of the respective fluxes from the effusion cells. For the ScxAl1-xN layers, Sc and Al were co-deposited under nitrogen-rich conditions with III/V ratio ˜ 0.85 at a substrate temperature of ˜495° C. Nitrogen-rich growth conditions were utilized to prevent any excess metal formation and direct reaction of Sc and Al. A more in-depth study of the justification of growth conditions and calibration to establish the effective III/V ratio is described elsewhere.(See, for example, J. Casamento, C. S. Chang, Y.-T. Shao, J. Wright, D. A. Muller, H. (Grace) Xing, and D. Jena, Appl. Phys. Lett. 117, 112101 (2020), which is incorporated by reference herein in its entirety and for all purposes.)

To test for ferroelectricity, a modified Sawyer-Tower (ST) setup was used. More details about the setup are described elsewhere.(See, for example, Ved Gund; Benyamin Davaji; Hyunjea Lee; Joseph Casamento; Huili Grace Xing; Debdeep Jena; Amit Lal, Towards Realizing the Low-Coercive Field Operation of Sputtered Ferroelectric ScxAl1-xN, 2021 21st International Conference on Solid-State Sensors, Actuators and Microsystems (Transducers) Year: 2021, which is incorporated by reference herein in its entirety and for all purposes.) The films were tested with continuous wave positive-up-negative-down (PUND) input waveforms and both triangular and pulses of equal rise, fall, and wait times. The I-V data from the PUND waveform was utilized to construct polarization-electric field (P-E) loops in a lateral geometry (e.g., both electrodes on top of the sample) with circular electrodes of 40 and 400 μm, respectively. The effective capacitance, formed by the two electrodes in series with the bottom n+GaN as the intermediate node is approximately equal to the capacitance formed between the 40 μm electrode and n+GaN due to the large difference in the sizes of the metal electrodes. The polarization is given as the polarization switching current, which is the polarization charge divided by the area of the metal electrode. The polarization charge is calculated from the polarization switching current integrated over time. The switching current in the positive and negative voltage cycles, respectively, is identified as the total measured current minus the displacement current and any leakage currents. Displacement currents follow the form I=C dV/dt and leakage currents scale with increased voltage. The electric field is given as the applied voltage divided by the ScxAl1-xN layer thickness.

For the purposes of describing and defining the present teachings, it is noted that the term “substantially” is utilized herein to represent the inherent degree of uncertainty that may be attributed to any quantitative comparison, value, measurement, or other representation. Similarly, the use of the word “about,” avoids a strict numerical boundary to the specified parameter. The usage of the term ‘about’ can usually be understood in light of the technology embodied by the invention. The term “substantially” is also utilized herein to represent the degree by which a quantitative representation may vary from a stated reference without resulting in a change in the basic function of the subject matter at issue.

What is claimed is:

1. A semiconductor device comprising;
a not intentionally doped III N layer, III being one or more Group 3 semiconductor element;
an other III N barrier layer, where the other III N includes at least one other III element different from the III element in the not intentionally doped III N layer, the other III N barrier layer being disposed on the not intentionally doped III N layer;
a Scₓ Al₁₋ₓ N layer epitaxially disposed on the other III N layer; and
a further III N layer, where III includes at least one further III element different from Aluminum;
the further III N layer disposed on the Scₓ Al₁₋ₓ N layer.

2. The semiconductor device of claim 1 wherein composition and thickness of the other III N barrier layer are selected such that a 2D electron gas forms at a boundary between the other III N barrier layer and the not intentionally doped III N layer.

3. The semiconductor device of claim 1 wherein the Scₓ Al₁₋ₓ N layer is a ferroelectric layer.

4. The semiconductor device of claim 3 wherein x is between about 0.1 and about 0.36.

5. The semiconductor device of claim 1 further comprising:
an n-doped drain region recessed into or disposed on the not intentionally doped III N layer and in contact with a first end of the other III N barrier layer and with a first end of the Scₓ Al₁₋ₓ N layer; and
an n-doped source region recessed into or disposed on the not intentionally doped III N layer and in contact with a second end of the other III N barrier layer and with a second end of the Scₓ Al₁₋ₓ N layer.

6. The semiconductor device of claim 5 wherein composition and thickness of the other III N barrier layer are selected such that a 2D electron gas forms at a boundary between the other III N barrier layer and the not intentionally doped III N layer.

7. The semiconductor device of claim 6 wherein the n-doped drain region is recessed into the not intentionally doped III N layer up to or beyond a location of the 2D electron gas forms; and wherein the n-doped source region is recessed into the not intentionally doped III N layer up to or beyond a location of the 2D electron gas forms.

8. The semiconductor device of claim 5 further comprising:
a first electrically conducting contact disposed on the n-doped source region;
a second electrically conducting contact disposed on the n-doped drain region; and
an electrically conductive gate contact disposed between the electrically conductive contacts on the n doped source and drain region and disposed on the further III N layer.

9. The semiconductor device of claim 7 wherein a maximum cutoff frequency is at least 150 GHz.

10. The semiconductor device of claim 1 wherein the not intentionally doped III N layer is a not intentionally doped GaN layer, the other III N barrier layer is an AlN layer, and the further III N layer is a GaN layer.

11. The semiconductor device of claim 10 further comprising:
an n-doped drain region recessed into or disposed on the not intentionally doped GaN layer and in contact with a first end of the AlN barrier layer and with a first end of the Scₓ Al₁₋ₓ N layer; and
an n-doped source region recessed into or disposed on the not intentionally doped GaN layer and in contact with a second end of the AlN barrier layer and with a second end of the Scₓ Al₁₋ₓ N layer.

12. The semiconductor device of claim 11 wherein thickness of the AlN layer is selected such that a 2D electron gas forms at a boundary between the AlN barrier layer and the not intentionally doped GaN layer.

13. The semiconductor device of claim 10 wherein the Scₓ Al₁₋ₓ N layer is a ferroelectric layer.

14. The semiconductor device of claim 13 wherein x is between about 0.1 and about 0.36.

15. The semiconductor device of claim 12 wherein the n-doped drain region is recessed into the not intentionally doped GaN layer up to or beyond a location of the 2D electron gas; and wherein the n-doped source region is recessed into the not intentionally doped GaN layer up to or beyond a location of the 2D electron gas.

16. The semiconductor device of claim 11 further comprising:
a first electrically conducting contact disposed on the n-doped source region;
a second electrically conducting contact disposed on the n-doped drain region; and
an electrically conductive gate contact disposed between the electrically conductive contacts on the n doped source and drain region and disposed on the GaN layer.

17. The semiconductor device of claim 15 wherein a maximum cutoff frequency is at least 150 GHz.

18. A semiconductor device comprising;
a not intentionally doped III N layer, III being one or more Group 3 semiconductor element; and
a Scₓ Al₁₋ₓ N layer epitaxially disposed on the not intentionally doped III N layer;
wherein a thickness of the Scₓ Al₁₋ₓ N layer is selected such that a 2D electron gas forms at a boundary between the Scₓ Al₁₋ₓ N layer and the not intentionally doped III N layer.

19. The semiconductor device of claim 18 wherein the not intentionally doped III N layer is a not intentionally doped GaN layer.

20. The semiconductor device of claim 18 wherein x is between about 0.1 and about 0.36; and wherein the Sc_{X}Al_{1-X}N layer is a ferroelectric layer.
